(19) United States
(12) Patent Application Publication
(10) Pub. No.: US 2026/0238204 A1
(43) Pub. Date: Aug. 13, 2026

(54) Switching Drive Device

(71) Applicant: Astemo, Ltd., Chiyoda-ku, Tokyo (JP)

(72) Inventors: Shintaro TANAKA, Tokyo (JP); Hangxian GAO, Tokyo (JP)

(21) Appl. No.: 19/155,290

(22) PCT Filed: May 29, 2024
(86) PCT No.: PCT/JP2024/019769

§ 371 Date: Aug. 11, 2025

(30) Foreign Application Priority Data
Jun. 13, 2023 (JP) 2023-097139

(51) Int. Cl. H03K 17/687; H02M 1/08

(52) U.S. Cl. CPC H03K 17/687; H02M 1/08

(57) ABSTRACT

A switching drive device that supplies a drive voltage or a drive current to a gate terminal of a semiconductor device includes: a first circuit that includes a turn-on resistor and a first switching element and charges the gate terminal when the semiconductor device is turned on; a second circuit that includes a turn-off resistor and a second switching element and discharges the gate terminal when the semiconductor device is turned off; a third circuit that is connected to the gate terminal, includes a gate resistor and a third switching element, and discharges or charges the gate terminal; and a control device that controls on/off of the first to third switching elements.

### TECHNICAL FIELD

The present invention relates to a switching drive device.

### BACKGROUND ART

To reduce the size and increase the power density of a power converter, it is necessary to reduce the loss of the power semiconductor. However, there is a trade-off relationship between a reduction in loss due to high-speed switching and an increase in surge at the time of switching. Therefore, conventionally, a multi-stage gate resistance drive circuit that suppresses a surge voltage within an allowable voltage while increasing the switching speed is known (see, for example, PTL 1).

### CITATION LIST

### Patent Literature

PTL 1: JP 2021-129396 A

### SUMMARY OF INVENTION

### Technical Problem

In the technique of PTL 1, the switching speed is increased through a P-type MOSFET (PMOS) of the charging circuit at the time of turn-on, and the switching speed is increased through an N-type MOSFET (NMOS) of the discharging circuit at the time of turn-off. However, by providing the PMOS and the NMOS, there is a problem that the circuit size and the circuit cost increase.

### Solution to Problem

A switching drive device according to an aspect of the present invention is a switching drive device that supplies a drive voltage or a drive current to a gate terminal of a semiconductor device and includes: a first circuit that includes a turn-on resistor and a first switching element and charges the gate terminal when the semiconductor device is turned on; a second circuit that includes a turn-off resistor and a second switching element and discharges the gate terminal when the semiconductor device is turned off; a third circuit that is connected to the gate terminal, includes a gate resistor and a third switching element, and discharges or charges the gate terminal; and a control device that controls on/off of the first to third switching elements. The control device controls charging by the first circuit and discharging or charging by the third circuit to execute a first turn-on operation mode and then executes a second turn-on operation mode having a lower speed than the first turn-on operation mode when the semiconductor device is turned on, and controls discharging by the second circuit and discharging or charging by the third circuit to execute a first turn-off operation mode and then executes a second turn-off operation mode having a lower speed than the first turn-off operation mode when the semiconductor device is turned off.

### Advantageous Effects of Invention

According to the present invention, it is possible to provide a switching drive device capable of suppressing a surge and increasing a switching speed while limiting a circuit scale to be small.

### BRIEF DESCRIPTION OF DRAWINGS

FIG. 1 is a diagram illustrating a part of a configuration of a power conversion device.

FIG. 2 is a diagram for explaining details of the switching drive device according to a first embodiment.

FIGS. 3(A), 3(B), 3(C), 3(D), 3(E), and 3(F) are diagrams illustrating waveform examples of respective signals at the time of turn-off in the first embodiment.

FIGS. 4(A), 4(B), 4(C), 4(D), 4(E), and 4(F) are diagrams illustrating waveform examples of respective signals at the time of turn-on in the first embodiment.

FIG. 5 is a diagram illustrating a configuration for detecting a state of a power semiconductor in the switching drive device.

FIG. 6(a) illustrates a relationship between a time width at the time of turn-off and a drain-source voltage, and FIG. 6(b) illustrates a relationship between a time width at the time of turn-off and a drain-source current.

FIGS. 7(a), 7(b), and 7(c) are diagrams for explaining a method of setting a time width at the time of turn-on.

FIG. 8 is a diagram illustrating a modification of the first embodiment.

FIG. 9 is a diagram for explaining a switching drive device according to a second embodiment.

FIGS. 10(A), 10(B), 10(C), 10(D), 10(E), and 10(F) are diagrams illustrating waveform examples of respective signals at the time of turn-off in the second embodiment.

FIGS. 11(A), 11(B), 11(C), 11(D), 11(E), and 11(F) are diagrams illustrating waveform examples of respective signals at the time of turn-on in the second embodiment.

FIG. 12 is a diagram illustrating a switching drive device according to a third embodiment.

### DESCRIPTION OF EMBODIMENTS

Hereinafter, embodiments of the present invention will be described with reference to the drawings. The following description and drawings are examples for describing the present invention, and are omitted and simplified as appropriate for the sake of clarity of description. In the following description, the same or similar elements and processes are denoted by the same reference numerals, and redundant description may be omitted. Note that the contents described below are merely examples of embodiments of the present invention, and the present invention is not limited to the following embodiments, and can be implemented in other various forms.

### First Embodiment

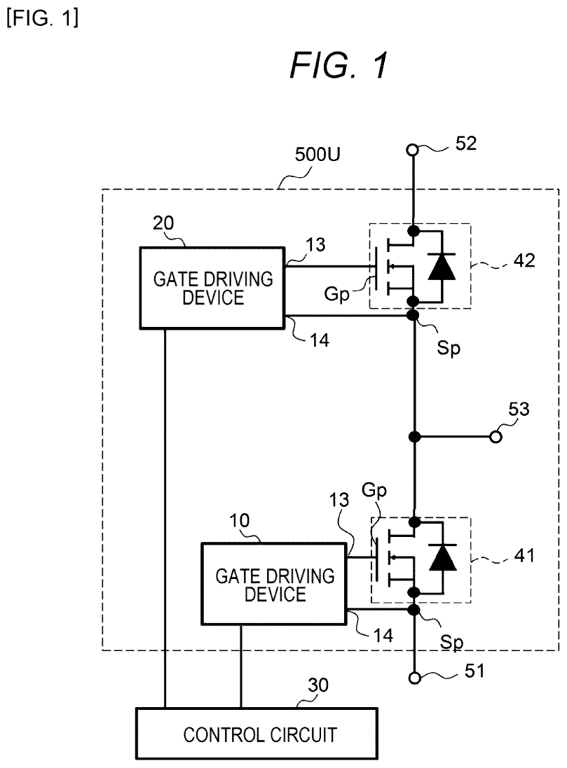

FIG. 1 is a diagram illustrating an application example of a switching drive device of the present embodiment, and is a diagram illustrating a part of a configuration of a power conversion device. The power conversion device drives, for example, an electric motor mounted on an electric vehicle. The electric motor includes a three-phase coil, and the power conversion device includes a three-phase switching arm for applying a predetermined energization pattern to the three-phase coil. FIG. 1 illustrates a three-phase switching arm 500U which is one phase of the three-phase switching arms 500U, 500V, and 500W provided in the power conversion device.

The three-phase switching arm 500U is provided with an upper arm power semiconductor 42 and a lower arm power semiconductor 41. For the power semiconductors 41 and 42, for example, semiconductor devices such as IGBTs, Si-MOSFETs, and GaN-MOSFETs are used. FIG. 1 illustrates a case where MOSFETs are used for the power semiconductors 41 and 42.

The power semiconductors 41 and 42 are provided with a main circuit high-voltage side terminal (collector terminal for IGBT, drain terminal for MOSFET), a main circuit low-voltage side terminal (emitter terminal for IGBT, source terminal for MOSFET), and a control terminal (gate terminal). It is also possible to further increase the number of power semiconductors connected in parallel in accordance with the desired output current value.

Positive electrode wiring 52 on the upper arm side is connected to a positive electrode terminal of a DC voltage source such as a battery (not illustrated). Negative electrode wiring 51 on the lower arm side is connected to a negative electrode terminal of the DC voltage source. The positive electrode wiring 52 is connected to a main circuit high-voltage side terminal (drain terminal) of the power semiconductor 42. The main circuit low-voltage side terminal (source terminal) of the power semiconductor 42 is connected to the output terminal 53 of the three-phase switching arm 500U and the main circuit high-voltage side terminal (drain terminal) of the power semiconductor 41. The main circuit low-voltage side terminal (source terminal) of the power semiconductor 41 is connected to the negative electrode wiring 51. The output terminal 53 is connected to a load such as an electric motor.

The gate terminal Gp and the source terminal Sp of the power semiconductor 41 are connected to the gate terminal 13 and the source terminal 14, respectively, of the gate driving device 10 that sends driving power to the power semiconductor 41. The gate terminal Gp and the source terminal Sp of the power semiconductor 42 are connected to the gate terminal 13 and the source terminal 14, respectively, of the gate driving device 20 that sends driving power to the power semiconductor 42.

The gate driving devices 10 and 20 are connected to the control circuit 30. The control circuit 30 includes, for example, a microcomputer or the like. The control circuit 30 outputs a control command for each of the gate driving devices 10 and 20 based on a drive command input from a host control device (not illustrated), and individually controls on/off of each of the power semiconductors 41 and 42. As a result, an AC voltage is output to a load such as an electric motor via the output terminal 53.

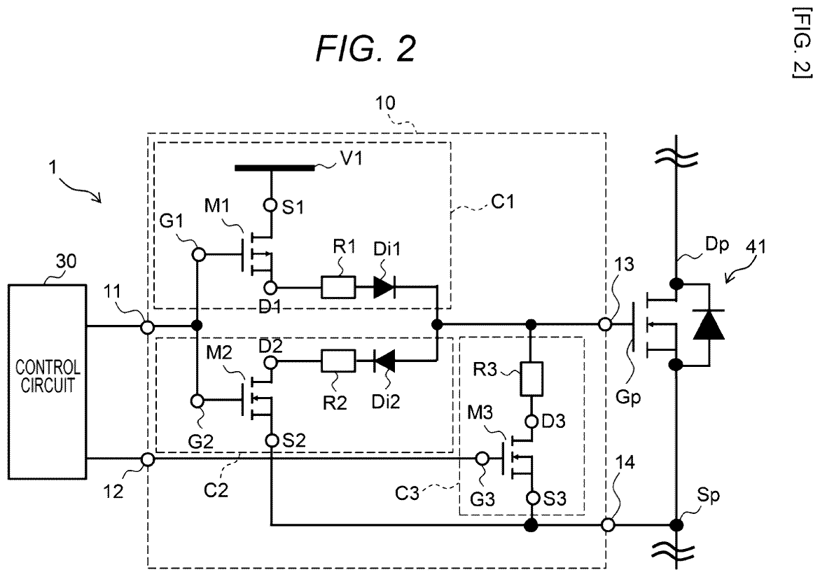

FIG. 2 is a diagram illustrating details of the switching drive device. The basic configuration of the switching drive device includes one of the gate driving devices 10 and 20 and the control circuit 30, and the example illustrated in FIG. 2 illustrates a switching drive device 1 including the gate driving device 10 and the control circuit 30. A switching drive device including the gate driving device 20 and the control circuit 30 also has the same configuration and operates similarly to the switching drive device 1 illustrated in FIG. 2. Hereinafter, the switching drive device 1 will be described as an example.

FIG. 2 is a diagram illustrating the power semiconductor 41 and the switching drive device 1 corresponding to the power semiconductor 41, and illustrates details of the gate driving device 10. The gate driving device 20 in FIG. 1 has a similar configuration to the gate driving device 10. The gate driving device 10 includes a first charging circuit C1 having a switching element M1, a first discharging circuit C2 having a switching element M2, and a second discharging circuit C3 having a switching element M3. In the following description, a case where the power semiconductor 41 and the switching elements M2 and M3 are N-type MOSFETs and the switching element M1 is a P-type MOSFET will be described as an example.

The first charging circuit C1 includes a positive-side power supply V1, a switching element M1, an on-gate resistor R1, and a backflow prevention diode Di1. The source-side terminal S1 of the switching element M1 is connected to the positive-side power supply V1. The gate terminal G1 of the switching element M1 is connected to a signal terminal 11 of the gate driving device 10. The drain-side terminal D1 of the switching element M1 is connected to one end of the on-gate resistor R1. The other end of the on-gate resistor R1 is connected to the anode of the backflow prevention diode Di1.

The first discharging circuit C2 includes a switching element M2, an off-gate resistor R2, and a backflow prevention diode Di2. The source-side terminal S2 of the switching element M2 is connected to the source terminal 14 of the gate driving device 10. The gate terminal G2 of the switching element M2 is connected to the signal terminal 11 of the gate driving device 10. The drain-side terminal D2 of the switching element M2 is connected to one end of the off-gate resistor R2. The other end of the off-gate resistor R2 is connected to the cathode of the backflow prevention diode Di2.

The second discharging circuit C3 includes a switching element M3 and a charge/discharge gate resistor R3. One end of the charge/discharge gate resistor R3 is connected to the gate terminal 13 of the gate driving device 10. The other end of the charge/discharge gate resistor R3 is connected to the drain-side terminal D3 of the switching element M3. The source-side terminal S3 of the switching element M3 is connected to the source terminal 14 of the gate driving device 10. The gate terminal G3 of the switching element M3 is connected to a signal terminal 12 of the gate driving device 10.

The cathode of the backflow prevention diode Di1 is connected to the anode of the backflow prevention diode Di2 and is connected to the gate terminal 13 of the gate driving device 10 and one end of the charge/discharge gate resistor R3. The first discharging circuit C2 and the second discharging circuit C3 are connected in parallel to the gate terminal 13. Note that the backflow prevention diodes Di1 and Di2 may be omitted.

The signal terminals 11 and 12 of the gate driving device 10 are connected to the control circuit 30. The gate terminal 13 of the gate driving device 10 is connected to the gate terminal Gp of the power semiconductor 41. The source terminal 14 of the gate driving device 10 is connected to the source terminal Sp of the power semiconductor 41. In the example illustrated in FIG. 2, the signal terminals 11 and 12 are connected to the common control circuit 30, but the signal terminals 11 and 12 may be individually connected to two control circuits provided independently.

### Description of Operation at Turn-Off

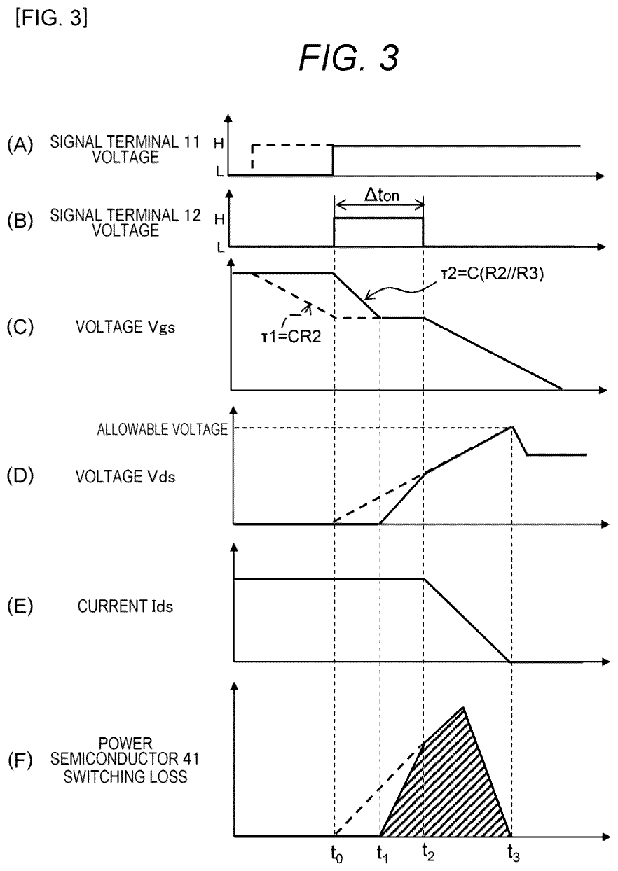

FIG. 3 is a diagram illustrating a waveform example of each signal when the power semiconductor 41 is turned off. Waveform (A) indicates a voltage waveform of the signal terminal 11. Waveform (B) indicates a voltage waveform of the signal terminal 12. Waveform (C) indicates a voltage between the gate and source (GpSp) of the power semiconductor 41 (hereinafter, referred to as gate-source voltage Vgs). Waveform (D) indicates a voltage between the drain and source (DpSp) of the power semiconductor 41 (hereinafter, referred to as drain-source voltage Vds). Waveform (E) indicates a current flowing between the drain and source (DpSp) of the power semiconductor 41 (hereinafter, referred to as drain-source current Ids). Waveform (F) indicates a waveform of switching loss of the power semiconductor 41. Note that a waveform indicated by a broken line in FIG. 3 indicates a signal waveform in a case of a configuration in which the second discharging circuit C3 is omitted in the circuit diagram illustrated in FIG. 2 (hereinafter, referred to as a conventional configuration).

As indicated by the solid line of waveform (A), at time to, a control command to turn off the power semiconductor 41 is input from the control circuit 30 to the signal terminal 11 of the gate driving device 10. That is, the voltage of the signal terminal 11 is switched from the L level to the H level. When this signal is input to the gate terminals G1 and G2 of the switching elements M1 and M2, the switching element M1, which is a P-type MOSFET, is switched from on to off, and the switching element M2, which is an N-type MOSFET, is switched from off to on.

Furthermore, as illustrated in waveform (B), at time t0, a control command to turn on the switching element M3 from off is input to the signal terminal 12. That is, the voltage of the signal terminal 12 is switched from the L level to the H level. When this signal is input to the gate terminal G3 of the switching element M3, the switching element M3, which is an N-type MOSFET, is switched from off to on. Note that the timing at which the ON control command is input to the signal terminal 12 may be later than time t0.

When the switching element M2 is turned on (the switching element M1 is turned off) at time t0, discharging of the gate-source capacitance of the power semiconductor 41 is started from the gate terminal Gp of the power semiconductor 41 in FIG. 2 via the backflow prevention diode Di2, the off-gate resistor R2, and the switching element M2. When the switching element M3 is turned on at time t0, discharging of the gate-source capacitance of the power semiconductor 41 is started from the gate terminal Gp of the power semiconductor 41 via the charge/discharge gate resistor R3 and the switching element M3. As a result, as indicated by the solid line of waveform (C), the gate-source voltage Vgs of the power semiconductor 41 starts to decrease.

When the gate-source voltage Vgs of the power semiconductor 41 reaches the mirror period at time t1, the drain-source voltage Vds of the power semiconductor 41 starts to increase as indicated by the solid line of waveform (D). In the case of the conventional configuration indicated by the broken line of waveform (C), when the gate capacitance of the power semiconductor 41 is C, the discharge time constant τ1 of the drain-source voltage Vds of the power semiconductor 41 is CR2. On the other hand, in the present embodiment, since the switching element M3 is also turned on at time t0 as illustrated in waveform (B), the discharge time constant τ2 of the drain-source voltage Vds of the power semiconductor 41 is C (R2//R3). R2//R3 represents a combined resistance of the resistors R2 and R3 connected in parallel. Therefore, while the switching element M3 is on (t1 to t2), the discharge speed of the gate-source voltage Vgs of the power semiconductor 41 is increased, and the drain-source voltage Vds is rapidly increased.

When the mirror period at the gate-source voltage Vgs ends at time t2 as indicated by waveform (C), the current (drain-source current Ids) flowing between the drain and source of the power semiconductor 41 starts to decrease as indicated by waveform (E). At this time t2, a control command to turn off the switching element M3 is input from the control circuit 30 to the signal terminal 12. That is, the voltage of the signal terminal 12 is switched from the H level to the L level. Note that the timing at which the OFF control command is input to the signal terminal 12 may be later than time t2. After time t2, the discharge time constant of the gate-source voltage Vgs of the power semiconductor 41 is CR2, which is the same as in the conventional configuration. Therefore, the surge voltage between the drain and source of the power semiconductor 41 related to the discharge time constant generated after time t2 is similar to that in the conventional configuration.

The switching loss amount of the power semiconductor 41 is represented by a total value obtained by integrating the product of the drain-source voltage Vds of the power semiconductor 41 and the drain-source current Ids of the power semiconductor 41. As illustrated in waveform (F), in the case of the conventional configuration (broken line), the off-gate resistor R2 is set large in order to suppress the drain-source voltage Vds of the power semiconductor 41 to be equal to or lower than the allowable voltage, and the switching loss occurs from time t0 to time t3. On the other hand, in the present embodiment, since the discharge speed is increased by turning on the switching element M3 at time t0, a loss occurs in a shorter period from time t1 to time t3 as illustrated in waveform (F). As described above, in the present embodiment, since the period during which the switching loss occurs is shorter than that in the case of the conventional configuration (broken line), the loss amount that is the time integral value of the loss is also less than that in the case of the conventional configuration. That is, in the first embodiment, the switching loss amount at turn-off can be reduced as compared with the case of the conventional configuration.

### Description of Operation at Turn-On

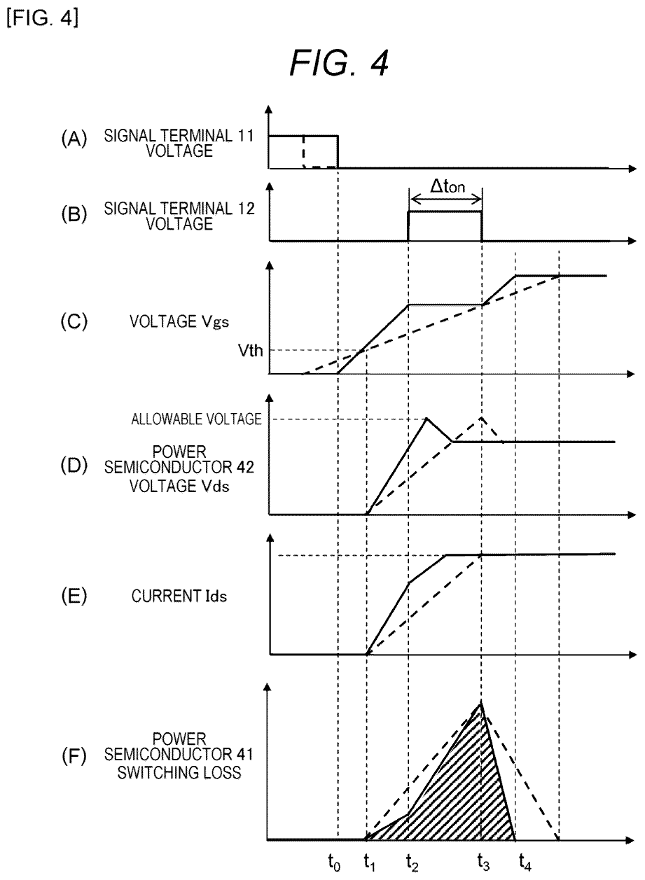

FIG. 4 is a diagram illustrating a waveform example of each signal when the power semiconductor 41 is turned on. Waveform (A) indicates a voltage waveform of the signal terminal 11. Waveform (B) indicates a voltage waveform of the signal terminal 12. Waveform (C) indicates a gate-source voltage Vgs of the power semiconductor 41. waveform (D) indicates a drain-source voltage Vds of the power semiconductor 42 on the upper arm side illustrated in FIG. 1. Waveform (E) indicates a drain-source current Ids of the power semiconductor 41. Waveform (F) indicates a switching loss of the power semiconductor 41. As in the case of FIG. 3, a waveform indicated by a broken line indicates a signal waveform in the case of the conventional configuration.

As indicated by the solid line of waveform (A), at time to, a control command to turn on the power semiconductor 41 is input from the control circuit 30 to the signal terminal 11 of the gate driving device 10. That is, the voltage of the signal terminal 11 is switched from the H level to the L level. When this signal is input to the gate terminals G1 and G2 of the switching elements M1 and M2, the switching element M1 is switched from off to on, and the switching element M2 is switched from on to off. When the switching element M1 is turned on, the gate-source capacitance of the power semiconductor 41 in FIG. 2 is charged by the charge current flowing through the positive-side power supply V1, the switching element M1, the backflow prevention diode Di1, and the on-gate resistor R1. As a result, the gate-source voltage Vgs of the waveform power semiconductor 41 starts to increase as indicated by the solid line of waveform (C).

At time t1, when the gate-source voltage Vgs of the power semiconductor 41 exceeds the threshold voltage Vth, as indicated by the solid lines of waveforms (D) and (E), the drain-source voltage Vds of the power semiconductor 42 on the upper arm side in FIG. 1 starts to increase, and the drain-source current Ids of the power semiconductor 41 starts to increase. That is, when the power semiconductor 41 on the lower arm side is turned on, the drain-source voltage Vds of the power semiconductor 41 decreases, and conversely, the drain-source voltage Vds of the power semiconductor 42 on the upper arm side that is in the off state increases.

As illustrated in waveform (B), at time t2, a control command to turn on the switching element M3 is input from the control circuit 30 to the signal terminal 12. That is, the voltage of the signal terminal 12 is switched from the L level to the H level. Note that the timing at which the ON control command is input to the signal terminal 12 may be earlier than time t2.

When the voltage of the signal terminal 12 reaches the H level at time t2, the switching element M3 is turned on, and the gate-source capacitance of the power semiconductor 41 is discharged from the gate terminal Gp of the power semiconductor 41 via the charge/discharge gate resistor R3 and the switching element M3. As a result, when the switching element M3 is on, the gate-source voltage Vgs of the power semiconductor 41 converges to a voltage value determined by the ratio between the charge/discharge gate resistor R3 of the second discharging circuit C3 and the on-gate resistor R1 of the first charging circuit C1. As indicated by the solid lines of waveforms (C) and (D), the gate-source voltage Vgs of the power semiconductor 41 is kept constant from time t2 to time t3. Therefore, the change in the drain-source current Ids of the power semiconductor 41 becomes gentle, and the increase in the drain-source voltage Vds of the power semiconductor 42 on the upper arm side becomes gentle and suppressed.

As illustrated in waveform (B), at time t3, a control command to turn off the switching element M3 is input from the control circuit 30 to the signal terminal 12. That is, the voltage of the signal terminal 12 is switched from the H level to the L level. Note that the timing at which the OFF control command is input to the signal terminal 12 may be later than time t3. As indicated by the solid line of waveform (F), the switching loss of the power semiconductor 41 occurs from time t1 to time t4.

In the case of the conventional configuration (broken line), the on-gate resistor R1 is set large in order to suppress the drain-source voltage Vds of the power semiconductor 42 on the upper arm side to be equal to or lower than the allowable voltage. On the other hand, in the present embodiment, the charging speed is reduced by turning on the switching element M3, and the drain-source voltage Vds of the power semiconductor 42 is suppressed to be equal to or lower than the allowable voltage. Therefore, the on-gate resistor R1 can be set smaller than that in the case of the conventional configuration, and the charging speed can be made higher than that in the conventional configuration during the period during which the switching element M3 is off. As a result, as illustrated in waveform (F), the period during which the loss occurs is shorter than that in the case of the conventional configuration (broken line). That is, in the first embodiment, the switching loss amount at turn-on can be reduced as compared with the case of the conventional configuration.

### Control Command Generation Method in Control Circuit 30

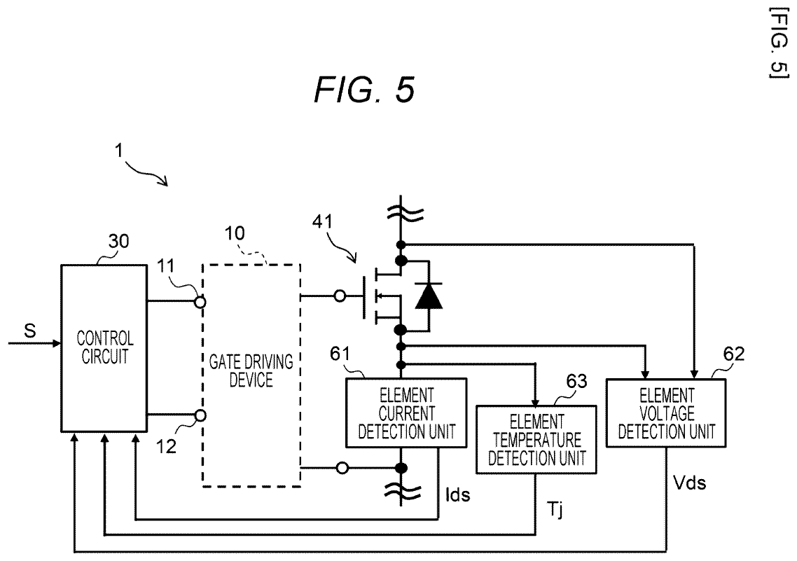

Next, a method of generating a control command in the control circuit 30 will be described. The control command from the control circuit 30 is preferably generated according to the state of the power semiconductor 41. FIG. 5 illustrates a circuit configuration related to the switching drive device 1 as in the case of FIG. 2, and includes a means for detecting the state of the power semiconductor 41.

In FIG. 5, as a means for detecting the state of the power semiconductor 41, an element current detection unit 61 that detects the drain-source current Ids of the power semiconductor 41, an element voltage detection unit 62 that detects the drain-source voltage Vds of the power semiconductor 41, and an element temperature detection unit 63 that detects the temperature Tj of the power semiconductor 41 are provided. The drive command S from a host control device and the state detection information (Ids, Vds, Tj) of each detection unit 61 to 63 are input to the control circuit 30.

The control circuit 30 transmits the control command to each of the signal terminal 11 and the signal terminal 12 of the gate driving device 10 based on only the drive command S or based on both the drive command S and the state detection information (Ids, Vds, Tj). As the state detection information of the power semiconductor 41, for example, a rise of a change rate of the drain-source voltage Vds, a fall of a change rate of the drain-source voltage Vds and the drain-source current Ids, and the like can be arbitrarily selected as information other than the above. As described above, the control circuit 30 can more appropriately control the switching operation of the power semiconductor 41 by generating the control command according to the detected state of the power semiconductor 41.

Although not illustrated, instead of the control circuit 30, a control circuit 30A that outputs a control command to the signal terminal 11 and a control circuit 30B that outputs a control command to the signal terminal 12 may be separately provided. The drive command S from the host and the state detection information (Ids, Vds, Tj) of the power semiconductor 41 are individually input to each of the control circuits 30 A and 30B.

Next, control using the state detection information (Ids, Vds, Tj) will be described. With respect to the control command input to the signal terminal 12 of the gate driving device 10 in FIG. 2, that is, the H level of the voltage of the signal terminal 12 in waveform (B) in FIGS. 3 and 4, the time width of the H level is set to Δton. The time width Δton may be set based on the drain-source voltage Vds of the power semiconductor 41 detected by the element voltage detection unit 62 in FIG. 5, or may be set based on the drain-source current Ids detected by the element current detection unit 61. In this case, both or only one of the detection values of the element voltage detection unit 62 and the element current detection unit 61 may be used.

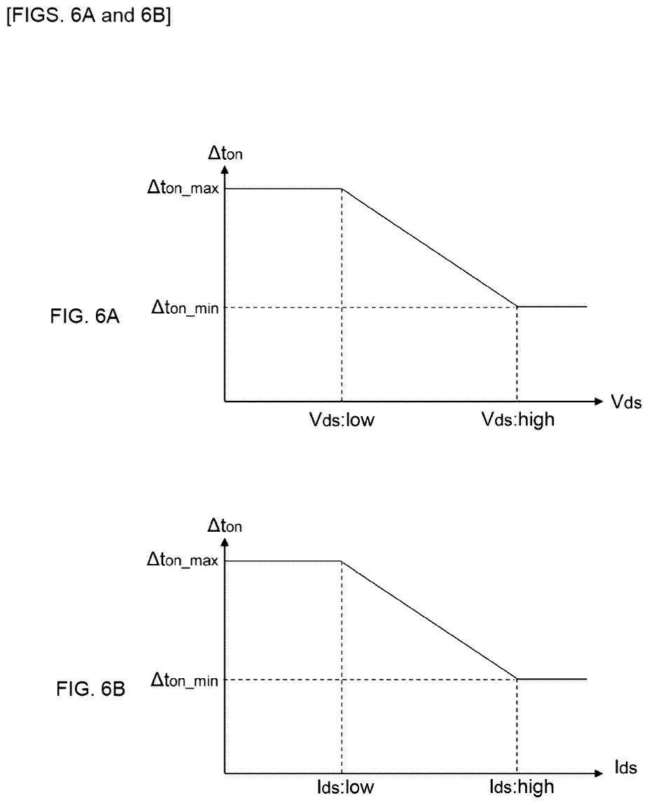

First, a method of generating a control command for the signal terminal 12 when the power semiconductor 41 is turned off will be described. The larger the time width Δton in FIG. 3, the higher the switching speed at the time of turn-off. FIG. 6(a) illustrates a case where the time width Δton at the time of turn-off is set based on the drain-source voltage Vds. As illustrated in FIG. 6(a), the time width Δton is set to be smaller as the detection value of the element voltage detection unit 62 is larger, and the time width Δton is set to be larger as the detection value is smaller. At that time, the time width Δton may be provided with a maximum value (Δton_max) or a minimum value (Δton_min). In addition, the value of the time width Δton does not have to be changed linearly, or a discrete value may be used. The reason for this setting is that the smaller the drain-source voltage Vds of the power semiconductor 41, the larger the voltage difference to the allowable voltage, so that the switching speed can be further increased. By setting the time width Δton as illustrated in FIG. 6(a), high-speed switching can be realized in a wider range according to the drain-source voltage Vds of the power semiconductor 41, and the switching loss is reduced.

FIG. 6(b) illustrates a case where the time width Δton at the time of turn-off is set based on the drain-source current Ids. In this case, the time width Δton is set to be smaller as the detection value of the element current detection unit 61 is larger, and the time width Δton is set to be larger as the detection value of the element current detection unit 61 is smaller. At that time, the time width Δton may be provided with a maximum value (Δton_max) or a minimum value (Δton_min). In addition, the value of the time width Δton does not have to be changed linearly, or a discrete value may be used. The reason for this setting is that the smaller the drain-source current Ids of the power semiconductor 41, the larger the voltage difference to the allowable voltage, so that the switching speed can be further increased. By setting the time width Δton as illustrated in FIG. 6(b), high-speed switching can be realized in a wider range according to the drain-source current Ids of the power semiconductor 41, and the switching loss is reduced.

Next, a method of generating a control command for the signal terminal 12 when the power semiconductor 41 is turned on will be described. The shorter the time width Δton illustrated in waveform (B) of FIG. 4, the faster the switching at the time of turn-on. In FIG. 4, the fall time of the time width Δton of the voltage signal of the signal terminal 12 may be, for example, the turn-on end time of the power semiconductor 41, or may be a value obtained by adding or subtracting an arbitrary time from the turn-on end time. In this case, the rise time of the time width Δton is a value obtained by subtracting the time width Δton from the fall time.

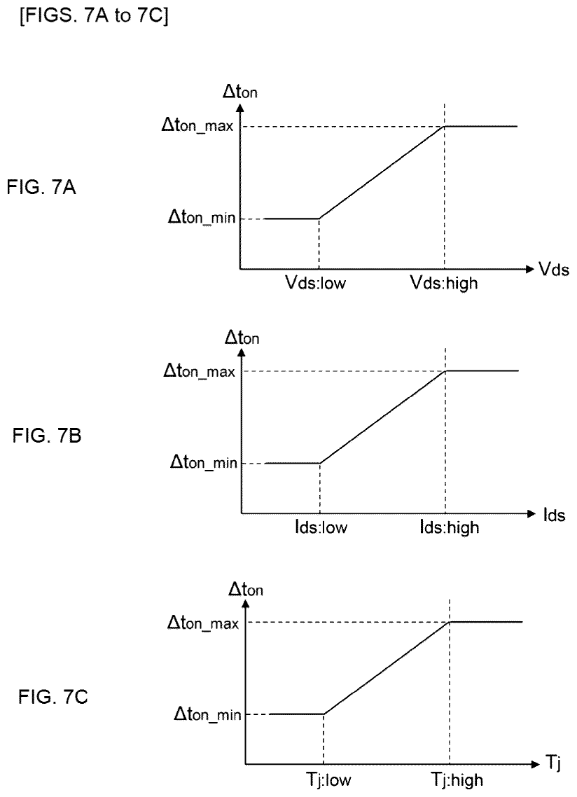

FIG. 7(a) illustrates a case where the time width Δton at the time of turn-on is set based on the drain-source voltage Vds detected by the element voltage detection unit 62. In this case, the time width Δton is set to be larger as the detection value of the element voltage detection unit 62 is larger, and the time width Δton is set to be smaller as the detection value is smaller. At that time, the time width Δton may be provided with a maximum value (Δton_max) or a minimum value (Δton_min). In addition, the value of the time width Δton does not have to be changed linearly, or a discrete value may be used. The reason for this setting is that the smaller the drain-source voltage Vds of the power semiconductor 41, the larger the voltage difference to the allowable voltage, so that the switching speed can be further increased by performing such a turn-on operation. By setting the time width Δton as illustrated in FIG. 7(a), high-speed switching can be realized in a wider range according to the drain-source voltage Vds of the power semiconductor 41, and the switching loss is reduced.

FIG. 7(b) illustrates a case where the time width Δton at the time of turn-on is set based on the drain-source current Ids detected by the element current detection unit 61. In this case, the time width Δton is set to be larger as the detection value of the element current detection unit 61 is larger, and the time width Δton is set to be smaller as the detection value of the element current detection unit 61 is smaller. At that time, the time width Δton may be provided with a maximum value (Δton_max) or a minimum value (Δton_min). In addition, the value of the time width Δton does not have to be changed linearly, or a discrete value may be used. The reason for this setting is that the smaller the drain-source current Ids of the power semiconductor 41 is, the larger the voltage difference to the allowable voltage is, so that the switching speed can be further increased by performing such a turn-on operation. By setting the time width Δton as illustrated in FIG. 7(b), high-speed switching can be realized in a wider range according to the drain-source current Ids of the power semiconductor 41, and the switching loss is reduced.

FIG. 7(c) illustrates a case where the time width Δton at the time of turn-on is set based on the temperature Tj of the power semiconductor 41 detected by the element temperature detection unit 63. In this case, the higher the temperature Tj, the larger the time width Δton, and the lower the temperature Tj, the smaller the time width Δton. At that time, the time width Δton may be provided with a maximum value (Δton_max) or a minimum value (Δton_min). In addition, the value of the time width Δton does not have to be changed linearly, or a discrete value may be used. The reason for this setting is that the lower the temperature Tj of the power semiconductor 41, the larger the voltage difference to the allowable voltage, so that the switching speed can be further increased by performing such a turn-on operation. By setting the time width Δton as illustrated in FIG. 7(c), high-speed switching can be realized in a wider range according to the temperature Tj of the power semiconductor 41, and the switching loss is reduced.

### Modification

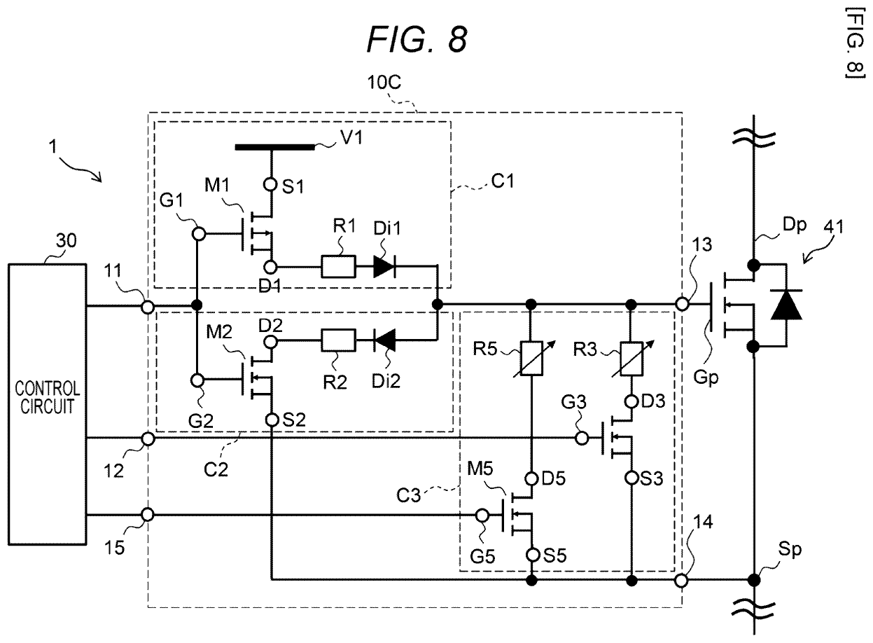

FIG. 8 is a diagram illustrating a modification of the first embodiment described above. In the modification illustrated in FIG. 8, the second discharging circuit C3 includes two discharging circuits connected in parallel. One of the discharging circuits connected in parallel includes a charge/discharge gate resistor 3R and a switching element M3, and the other includes a charge/discharge gate resistor 5R and a switching element M5. In the example illustrated in FIG. 8, the charge/discharge gate resistors 3R and 5R are variable resistors, but may not be variable resistors. In the second discharging circuit C3, three or more discharging circuits may be connected in parallel.

The values of the charge/discharge gate resistors 3R and 5R may be determined according to a control command of the control circuit 30, or may be determined using detection values of the element current detection unit 61, the element voltage detection unit 62, and the element temperature detection unit 63 illustrated in FIG. 5. In the case of the configuration of FIG. 8, for example, in the case of turn-off, the speed can be further increased by turning on all of the switching elements M2, M3, and M5. Also in the case of the second discharging circuit C3 illustrated in FIG. 2, by making the charge/discharge gate resistor R3 a variable resistor, for example, by controlling the value of the variable resistor according to the value of the element temperature Tj, charge and discharge control can be more appropriately performed.

### Second Embodiment

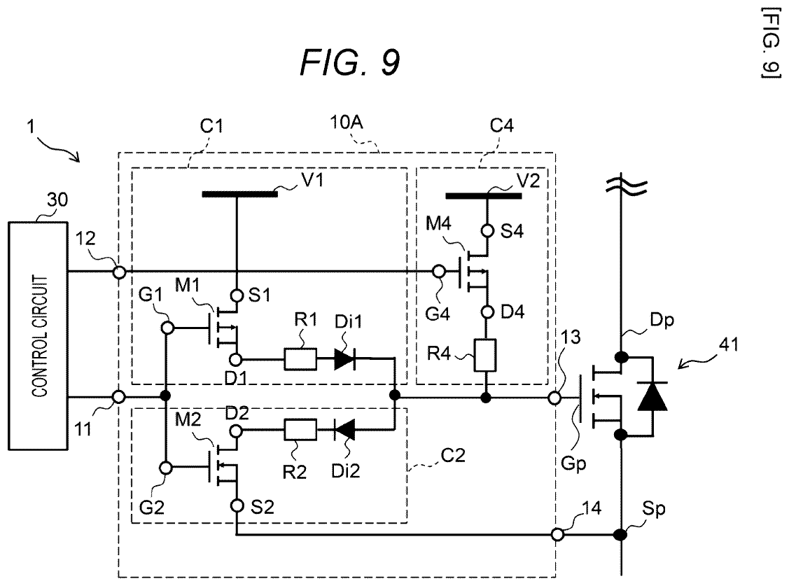

FIG. 9 is a diagram illustrating a switching drive device 1 according to a second embodiment of the present invention. The switching drive device 1 illustrated in FIG. 9 includes a control circuit 30 and a gate driving device 10A that sends drive power to a power semiconductor 41. Although not illustrated, the switching drive device related to the power semiconductor 42 on the upper arm side also includes a gate driving device having the same configuration as the gate driving device 10A.

The gate driving device 10A includes a first charging circuit C1 having a switching element M1, a first discharging circuit C2 having a switching element M2, and a second charging circuit C4 having a switching element M4. In the following description, a case where the power semiconductor 41 and the switching element M2 are N-type MOSFETs and the switching elements M1 and M4 are P-type MOSFETs will be described as an example.

The first charging circuit C1 and the first discharging circuit C2 of the gate driving device 10A have the same configuration as the first charging circuit C1 and the first discharging circuit C2 of the gate driving device 10 illustrated in FIG. 2. The second charging circuit C4 includes a switching element M4 and a charge/discharge gate resistor R4. The source-side terminal S4 of the switching element M4 is connected to the positive-side power supply V2. The gate terminal G4 of the switching element M4 is connected to the signal terminal 12 of the gate driving device 10A. The drain-side terminal D4 of the switching element M4 is connected to one end of the charge/discharge gate resistor R4. The other end of the charge/discharge gate resistor R4 is connected to the gate terminal 13 of the gate driving device 10A.

The cathode of the backflow prevention diode Di1 is connected to the anode of the backflow prevention diode Di2 and is also connected to the gate terminal 13 of the gate driving device 10A and the other end of the charge/discharge gate resistor R4. The first charging circuit C1 and the second charging circuit C4 are connected in parallel to the gate terminal 13. Note that the backflow prevention diodes Di1 and Di2 may be omitted.

The signal terminals 11 and 12 of the gate driving device 10A are connected to the control circuit 30. The gate terminal 13 of the gate driving device 10A is connected to the gate terminal Gp of the power semiconductor 41. The source terminal 14 of the gate driving device 10A is connected to the source terminal Sp of the power semiconductor 41. In the example illustrated in FIG. 9, the signal terminals 11 and 12 are connected to the common control circuit 30, but the signal terminals 11 and 12 may be individually connected to two control circuits provided independently. The potentials of the positive-side power supplies V1 and V2 may be different from each other, but are generally set equal to each other, and a case where the same potential is set is described as an example also in the present embodiment.

### Description of Operation at Turn-Off

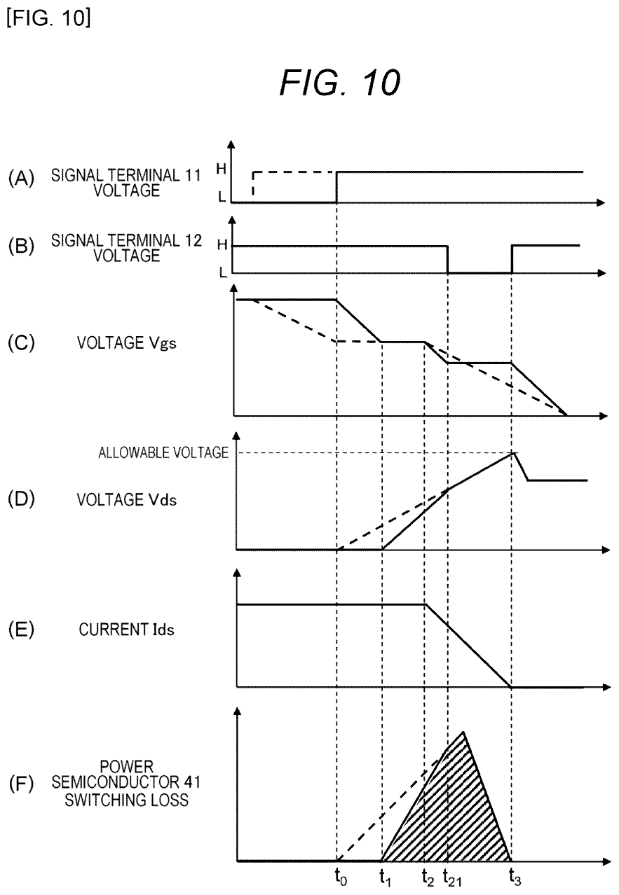

FIG. 10 is a diagram illustrating a waveform example of each signal when the power semiconductor 41 is turned off. Waveform (A) indicates a voltage waveform of the signal terminal 11. Waveform (B) indicates a voltage waveform of the signal terminal 12. Waveform (C) indicates a gate-source voltage Vgs of the power semiconductor 41. Waveform (D) indicates drain-source voltage Vds of the power semiconductor 41. Waveform (E) indicates a drain-source current Ids of the power semiconductor 41. Waveform (F) indicates a waveform of switching loss of the power semiconductor 41. Note that a waveform indicated by a broken line in FIG. 10 indicates a signal waveform in a case of a conventional configuration in which the second charging circuit C4 is omitted in the circuit diagram illustrated in FIG. 9.

As indicated by the solid line of waveform (A), at time to, a control command to turn off the power semiconductor 41 is input from the control circuit 30 to the signal terminal 11 of the gate driving device 10. That is, the voltage of the signal terminal 11 is switched from the L level to the H level. When this signal is input to the gate terminals G1 and G2 of the switching elements M1 and M2, the switching element M1, which is a P-type MOSFET, is switched from on to off, and the switching element M2, which is an N-type MOSFET, is switched from off to on.

When the switching element M2 is turned on (the switching element M1 is turned off) at time t0, discharging of the gate-source capacitance of the power semiconductor 41 is started from the gate terminal Gp of the power semiconductor 41 via the backflow prevention diode Di2, the off-gate resistor R2, and the switching element M2. As a result, as indicated by the solid line of waveform (C), the gate-source voltage Vgs of the power semiconductor 41 starts to decrease.

As described in the first embodiment, in the case of the conventional configuration (broken line), the value of the off-gate resistor R2 is set large in order to suppress the drain-source voltage Vds of the power semiconductor 41 to be equal to or lower than the allowable voltage. On the other hand, the value of off-gate resistor R2 of the first discharging circuit C2 in the second embodiment is set smaller than that in the conventional configuration. For example, in the example illustrated in FIG. 10, the value of the off-gate resistor R2 is set such that the discharge time constant of the gate-source voltage Vgs from time t0 to time t1 is the same as the time constant τ2 illustrated in FIG. 3. Therefore, the slope of the solid line of the gate-source voltage Vgs from time t0 to time t1 in FIG. 10 is the same as the slope of the solid line from time t0 to time t1 of waveform (C) in FIG. 3.

When the gate-source voltage Vgs of the power semiconductor 41 reaches the mirror period at time t1, the drain-source voltage Vds of the power semiconductor 4 starts to increase as indicated by the solid line of waveform (D). As indicated by the solid line of waveform (C), when the mirror period for the gate-source voltage Vgs of the power semiconductor 41 ends at time t2, the drain-source current Ids of the power semiconductor 41 starts to decrease as indicated by waveform (E).

As illustrated in waveform (B), at time t21, a control command to turn on the switching element M4 is input from the control circuit 30 to the signal terminal 12. That is, the voltage of the signal terminal 12 is switched from the H level to the L level. Note that the timing (time t21) at which the ON control command is input to the signal terminal 12 may be later than time t2.

When the switching element M4 is turned on at time t21, a charge current flows via the positive-side power supply V2, the switching element M4, and the charge/discharge gate resistor R4. As a result, when the switching element M4 is on, the gate-source voltage Vgs of the power semiconductor 41 converges to a voltage value determined by the ratio between the charge/discharge gate resistor R4 of the second charging circuit C4 and the off-gate resistor R2 of the first discharging circuit C2. As described above, by turning on the switching element M4 while discharging is being performed in the first discharging circuit C2, the discharge speed is reduced, and the drain-source voltage Vds of the power semiconductor 41 is suppressed to be equal to or lower than the allowable voltage.

Therefore, as described above, the value of the off-gate resistor R2 can be set smaller than that in the case of the conventional configuration, and the discharge speed can be made higher than that in the conventional configuration in the period during which the switching element M3 is off. As a result, as indicated by the solid line of waveform (F), the period during which the loss occurs becomes shorter than the case of the conventional configuration (broken line) in which the off-gate resistor R2 is increased. That is, also in the second embodiment, the switching loss amount at turn-off can be reduced as compared with the case of the conventional configuration.

In the example illustrated in FIG. 10, time t3 at the timing when an OFF control command is input to the signal terminal 12, that is, the timing when the L level is switched to the H level, may be the same time as time t3 at which the drain-source current Ids becomes 0, or may be later than time t3.

### Description of Operation at Turn-On

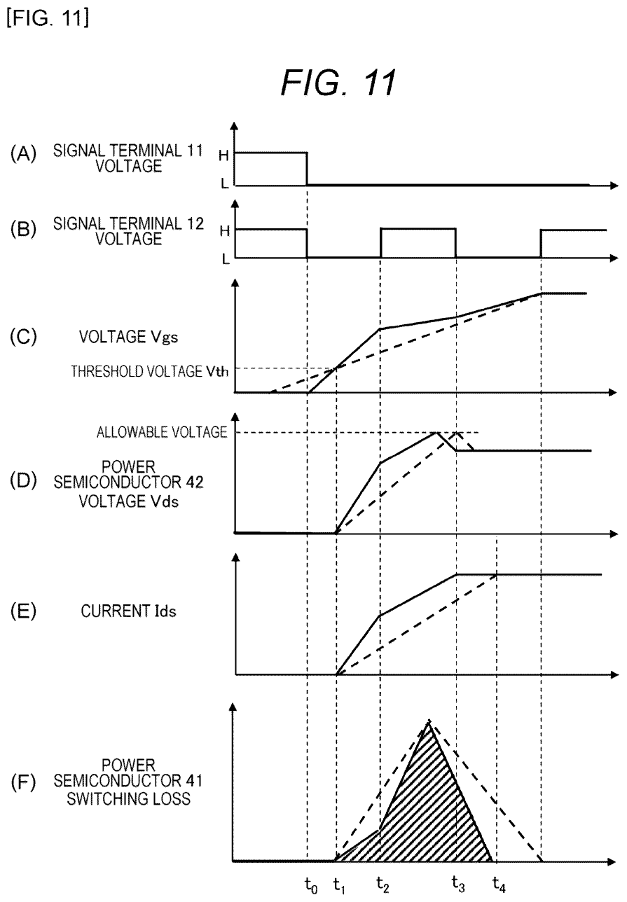

FIG. 11 is a diagram illustrating a waveform example of each signal when the power semiconductor 41 is turned on. Waveform (A) indicates a voltage waveform of the signal terminal 11. Waveform (B) indicates a voltage waveform of the signal terminal 12. Waveform (C) indicates a gate-source voltage Vgs of the power semiconductor 41. waveform (D) indicates a drain-source voltage Vds of the power semiconductor 42 on the upper arm side illustrated in FIG. 1. Waveform (E) indicates a drain-source current Ids of the power semiconductor 41. Waveform (F) indicates a switching loss of the power semiconductor 41. In addition, a waveform indicated by a broken line indicates a signal waveform in a case of a conventional configuration in which the second charging circuit C4 is omitted in the circuit diagram illustrated in FIG. 9.

As illustrated in waveform (A), at time t0, a control command to turn on the power semiconductor 41 is input from the control circuit 30 to the signal terminal 11 of the gate driving device 10. That is, the voltage of the signal terminal 11 is switched from the H level to the L level. When this signal is input to the gate terminals G1 and G2 of the switching elements M1 and M2, the switching element M1 is switched from off to on, and the switching element M2 is switched from on to off. When the switching element M1 is turned on (the switching element M2 is turned off) at time t0, a charge current flows via the positive-side power supply V1, the switching element M1, the backflow prevention diode Di1, and the on-gate resistor R1.

In addition, as illustrated in waveform (B), a control command to turn on the switching element M4 from off at time t0 is input to the signal terminal 12 from the control circuit 30. That is, the voltage of the signal terminal 12 is switched from the H level to the L level. When the switching element M4 is turned on at time t0, a charge current flows via the positive-side power supply V2, the switching element M4, and the charge/discharge gate resistor R4. Note that the timing at which the ON control command is input to the signal terminal 12 may be later than time t0.

When charging is performed only by the first charging circuit C1 as in the conventional configuration not including the second charging circuit C4, and the gate capacitance of the power semiconductor 41 is C, the charging time constant τ3 of the drain-source voltage Vds of the power semiconductor 41 is CR1. On the other hand, in the second embodiment, since charging is performed by the first charging circuit C1 and the second charging circuit C4 connected in parallel, the charging time constant τ4 of the drain-source voltage Vds of the power semiconductor 41 is C (R1//R4). R1//R4 represents a combined resistance of the resistors R1 and R4 connected in parallel. Therefore, while the switching element M4 is turned on, the charging speed of the gate-source voltage Vds of the power semiconductor 41 is increased, and the drain-source voltage Vds rapidly increases as compared with a conventional case.

As indicated by the solid line of waveform (C), when the gate-source voltage Vgs of the power semiconductor 41 exceeds the threshold voltage (Vth) at time t1, as indicated by the solid lines of the waveforms (D) and (E), the drain-source voltage Vds of the power semiconductor 42 on the upper arm side starts to increase and the drain-source current Ids of the power semiconductor 41 starts to increase.

As illustrated in waveform (B), at time t2, a control command to turn off the switching element M4 is input from the control circuit 30 to the signal terminal 12. That is, the voltage of the signal terminal 12 is switched from the L level to the H level. Note that the timing at which the OFF control command is input to the signal terminal 12 may be later than time t2. After time t2, the charging time constant of the gate-source voltage Vgs of the power semiconductor 41 is CR1, which is the same as in the case of the conventional configuration. Therefore, the surge voltage between the drain and source of the power semiconductor 41 related to the charging time constant generated after time t2 is similar to that in the conventional configuration.

As indicated by the solid line of waveform (F), the switching loss of the power semiconductor 41 occurs between time t1 and time t4, and the loss period can be shortened as compared with the case of the conventional configuration (broken line) in which the on-gate resistor R1 is increased in order to suppress the drain-source voltage Vds of the power semiconductor 42 of the pair arm. That is, also in the second embodiment, the switching loss amount at turn-on can be reduced as compared with the case of the conventional configuration.

After time t3, as illustrated in waveform (B), a control command to turn on the switching element M4 may be input from the control circuit 30 to the signal terminal 12 to perform high-speed switching. As a result, when the switching element M4 is on, the gate-source voltage Vgs rises at a high speed as illustrated in waveform (C), so that the turn-on operation is speeded up, and the switching of the power semiconductor 41 is further reduced.

Also in the case of the second embodiment, a configuration including the element current detection unit 61, the element voltage detection unit 62, and the element temperature detection unit 63 illustrated in FIG. 5 can be applied.

### Third Embodiment

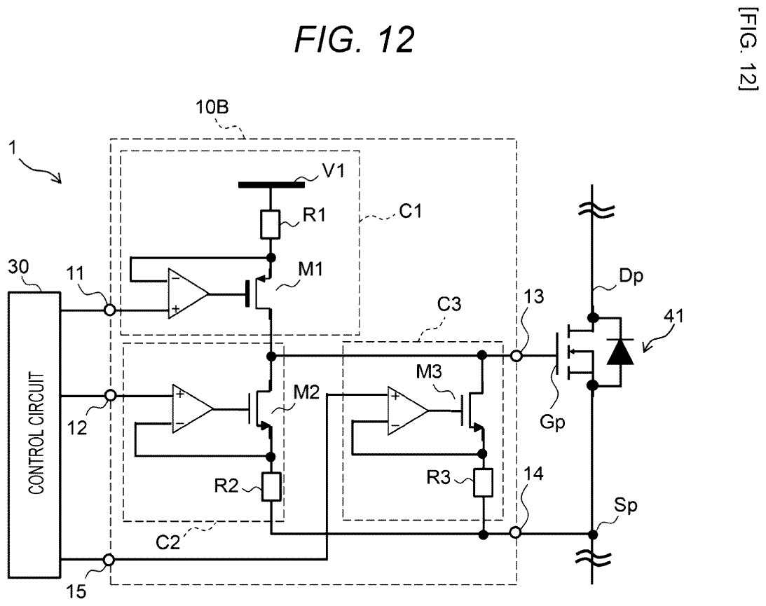

FIG. 12 is a diagram illustrating a switching drive device 1 according to a third embodiment. The gate driving device 10 illustrated in FIG. 2 is a voltage-driven type gate driving device, but the gate driving device 10B illustrated in FIG. 12 illustrates an example of a case where the voltage-driven type is changed to the constant-current driven type. The switching elements M1, M2, and M3 are replaced with constant-current driven type switching elements. In FIG. 12, the method using the operational amplifier is adopted, but the method using the operational amplifier may not be adopted. A control command is input from the control circuit 30 to the input terminal on the positive side of each operational amplifier via the signal terminals 11,12, and 15 of the gate driving device 10B.

In addition, all of the switching elements M1, M2, and M3 may not be the constant current type driving type, and the voltage-driven type and the constant-current driven type may be used in combination. For example, when it is desired to set the turn-off to the constant-current driven type and the turn-on to the voltage-driven type, the switching elements M2 and M3 may have the configuration illustrated in FIG. 12, and the switching element M1 may have the configuration illustrated in FIG. 2. In the case of the voltage-driven type, the circuit configuration is simple, but the amount of current varies depending on the load. On the other hand, the constant-current driven type is easy to control because the current is constant, but the circuit configuration is slightly more complicated than the case of the voltage-driven type.

In FIG. 12, the voltage-driven switching elements M1, M2, and M3 are replaced with the constant-current driven switching elements in the configuration of FIG. 2, but the constant-current driven switching elements can also be applied in the configuration of FIG. 9.

According to the embodiment and the modification of the present invention described above, the following operational effects are obtained.

(1) As illustrated in FIGS. 2 to 4, 9 to 12, and the like, the switching drive device 1 that supplies a drive voltage or a drive current to the gate terminal Gp of the power semiconductor 41 includes a first circuit (first charging circuit C1) that includes the turn-on resistor R1 and the first switching element M1 and charges the gate terminal Gp when the power semiconductor 41 is turned on, a second circuit (first discharging circuit C2) that includes the turn-off resistor R2 and the second switching element M2 and discharges the gate terminal Gp when the power semiconductor 41 is turned off, and a third circuit (second discharging circuit C3 or second charging circuit C4) that is connected to the gate terminal Gp, includes the gate resistor (charge/discharge gate resistor R3 or R4) and the third switching element M3 or M4, and discharges or charges the gate terminal Gp, and a control device (control circuit 30) that controls on/off of the first to third switching elements M1 to M4.

Then, when the power semiconductor 41 is turned on, the control circuit 30 controls charging by the first circuit (first charging circuit C1) and discharging or charging by the third circuit (second discharging circuit C3 or second charging circuit C4) to execute the first turn-on operation mode at time to to time t2 in FIG. 4 or 11, and then executes the second turn-on operation mode, which has a lower speed than the first turn-on operation mode, at time t2 to time t3 in FIG. 4 or time t2 to time t3 in FIG. 11. By executing the first and second turn-on operation modes in this manner, it is possible to shorten the period during which the switching loss occurs in the power semiconductor 41 while suppressing the surge voltage at the time of turn-on. As a result, the switching loss amount at the time of turn-on can be reduced.

In addition, when the power semiconductor 41 is turned off, discharging by the second circuit (first discharging circuit C2) and discharging or charging by the third circuit (second discharging circuit C3 or second charging circuit C4) are controlled to execute the first turn-off operation mode at time to to time t2 in FIG. 3 or time t0 to time t21 in FIG. 10, and then the second turn-off operation mode, which has a lower speed than the first turn-off operation mode, is executed at time t2 to time t3 in FIG. 3 or time t21 to time t3 in FIG. 10. By executing the first and second turn-off operation modes in this manner, it is possible to shorten the period during which the switching loss occurs in the power semiconductor 41 while suppressing the surge voltage at the time of turn-off. As a result, the switching loss amount at the time of turn-off can be reduced.

As described above, the switching drive device 1 can achieve surge suppression and reduction of the switching loss amount at the time of turn-on and turn-off by simply adding the third circuit (second discharging circuit C3 or second charging circuit C4) to the first circuit (first charging circuit C1) and the second circuit (first discharging circuit C2), that is, while suppressing an increase in cost.

(2) In the above (1), as shown in FIGS. 2 and 12, the third circuit is the second discharging circuit C3 provided in parallel with the first discharging circuit C2 (second circuit). In the first turn-on operation mode from time t0 to time t2 in FIG. 4, charging by the first charging circuit C1 (first circuit) is performed, and in the second turn-on operation mode from time t2 to time t3, charging by the first charging circuit C1 and discharging by second discharging circuit C3 are performed. In the first turn-off operation mode from time t0 to time t2 in FIG. 3, discharging by the first discharging circuit C2 and discharging by the second discharging circuit C3 are performed, and in the second turn-off operation mode from time t2 to time t3, discharging by the first discharging circuit C2 is performed.

In the switching drive device 1 of FIGS. 2 and 12, in the second turn-on operation mode illustrated in FIG. 4, discharging by the second discharging circuit C3 is performed while charging by the first charging circuit C1 is performed to suppress the surge due to the low charging speed, so that the on-gate resistor R1 can be set smaller than the conventional one. As a result, the charging speed in the first turn-on operation mode can be made higher than before, and the switching loss amount at the time of turn-on can be reduced. In the first turn-off operation mode illustrated in FIG. 3, discharging by the first discharging circuit C2 and discharging by the second discharging circuit C3 are executed, so that the discharge time constant τ2 of the drain-source voltage Vds of the power semiconductor 41 becomes C (R2//R3), and the discharge speed of the gate-source voltage Vds of the power semiconductor 41 is increased. As a result, the period during which the switching loss occurs is shortened as compared with a conventional case, and the switching loss amount at the time of turn-off can be reduced.

(3) In the above (1), as shown in FIG. 9, the third circuit is a second charging circuit C4 provided in parallel with the first charging circuit C1 (first circuit). In the first turn-on operation mode from time t0 to time t2 in FIG. 11, charging by the first charging circuit C1 and charging by the second charging circuit C4 are performed, and in the second turn-on operation mode from time t2 to time t3, charging by the first charging circuit C1 is performed. In the first turn-off operation mode from time t0 to time t21 in FIG. 10, discharging by the first discharging circuit C2 is performed, and in the second turn-off operation mode from time t21 to time t3, discharging by the first discharging circuit C2 and charging by the second charging circuit C4 are performed.

In the switching drive device 1 of FIG. 9, since the charging by the first charging circuit C1 and the charging by the second charging circuit C4 are performed in the first turn-on operation mode at time t0 to time t2 of FIG. 11, the charging time constant τ4 of the drain-source voltage Vds of the power semiconductor 41 is C (R1//R4). Therefore, the discharge speed of the gate-source voltage Vds of the power semiconductor 41 is increased, the period during which the switching loss occurs is shortened as compared with a conventional case, and the switching loss amount at the time of turn-on can be reduced. In addition, in the second turn-off operation mode illustrated in FIG. 10, since the discharge speed is reduced by turning on the switching element M4 while discharging is being performed in the first discharging circuit C2, the off-gate resistor R2 can be set to be smaller than the conventional one. As a result, the discharge speed in the first turn-off operation mode is increased, the period during which the switching loss occurs is shortened as compared with a conventional case, and the switching loss amount at the time of turn-off can be reduced.

(4) In the above (1), as shown in FIG. 2, when the third circuit is the second discharging circuit C3 that performs discharging, the second turn-on operation mode is executed, and then the first turn-on operation mode in which charging by the first charging circuit C1 (first circuit) is performed is re-executed as with after time t3 in FIG. 4. When the third circuit is the second charging circuit C4 that performs charging as shown in FIG. 9, the second turn-off operation mode in FIG. 10 is executed, and then the first turn-off operation mode in which discharging by the first discharging circuit C2 (second circuit) is performed is re-executed as with after time t3 in FIG. 10. By performing such control, the switching operation of the power semiconductor 41 can be performed at a higher speed.

(5) In the above (1), as illustrated in FIG. 5 and the like, a detection unit (element current detection unit 61, element voltage detection unit 62, element temperature detection unit 63) that detects at least one of the voltage Vds, the current Ids, and the temperature Tj of the power semiconductor 41 is further included, and the control circuit 30 controls on/off of the third switching element M3 based on the detection information (voltage Vds, current Ids, and temperature Tj) of the detection unit. As described above, by controlling on/off of the third switching element M3 according to the detected state of the power semiconductor 41, the switching operation of the power semiconductor 41 can be more appropriately controlled.

(6) For example, in the above (2), the discharge period (time width Δton) by the third circuit (second discharging circuit C3) in the first turn-off operation mode from time t0 to time t2 in FIG. 3 is set longer as the input voltage (drain-source voltage Vds) of the power semiconductor 41 or the drain-source current Ids flowing through the power semiconductor 41 decreases, as illustrated in FIG. 6(a) and 6(b).

(7) For example, in the above (2), as illustrated in FIG. 7, the discharge period (time width Δton) by the third circuit (second discharging circuit C3) in the second turn-on operation mode from time t2 to time t3 in FIG. 4 is set longer as the input voltage Vds of the power semiconductor 41, the drain-source current Ids flowing through the power semiconductor 41, or the device temperature Tj of the power semiconductor 41 increases.

The embodiments and various modifications described above are merely examples, and the present invention is not limited to these contents as long as the characteristics of the invention are not impaired. The embodiments and various modifications described above are merely examples, and the present invention is not limited to these contents. Other aspects conceivable within the scope of the technical idea of the present invention are also included within the scope of the present invention.

### REFERENCE SIGNS LIST

1 switching drive device
10, 10A, 10B, 20 gate driving device
30 control circuit
41, 42 power semiconductor
51 negative electrode wiring
52 positive electrode wiring
53 output terminal
61 element current detection unit
62 element voltage detection unit
63 element temperature detection unit
C1 first charging circuit
C2 first discharging circuit
C3 second discharging circuit
Di1, Di2 backflow prevention diode
M1, M2, M3, M4, M5 switching element
R1 on-gate resistor
R2 off-gate resistor
R3, R4, R5 charge/discharge gate resistor
V1, V2 positive-side power supply
Δton time width

1. A switching drive device that supplies a drive voltage or a drive current to a gate terminal of a semiconductor device, the switching drive device comprising:
a first circuit that includes a turn-on resistor and a first switching element and charges the gate terminal when the semiconductor device is turned on;
a second circuit that includes a turn-off resistor and a second switching element and discharges the gate terminal when the semiconductor device is turned off;
a third circuit that is connected to the gate terminal, includes a gate resistor and a third switching element, and discharges or charges the gate terminal; and
a control device that controls on/off of the first to third switching elements,
wherein the control device
controls charging by the first circuit and discharging or charging by the third circuit when the semiconductor device is turned on to execute a first turn-on operation mode, and then executes a second turn-on operation mode having a lower speed than the first turn-on operation mode, and
controls discharging by the second circuit and discharging or charging by the third circuit when the semiconductor device is turned off to execute a first turn-off operation mode, and then executes a second turn-off operation mode having a lower speed than the first turn-off operation mode.

2. The switching drive device according to claim 1, wherein
the third circuit is a discharging circuit provided in parallel with the second circuit,
charging by the first circuit is performed in the first turn-on operation mode,
charging by the first circuit and discharging by the third circuit are performed in the second turn-on operation mode,
discharging by the second circuit and discharging by the third circuit are performed in the first turn-off operation mode, and
discharging by the second circuit is performed in the second turn-off operation mode.

3. The switching drive device according to claim 1, wherein
the third circuit is a charging circuit provided in parallel with the first circuit,
charging by the first circuit and charging by the third circuit are performed in the first turn-on operation mode,
charging by the first circuit is performed in the second turn-on operation mode,
discharging by the second circuit is performed in the first turn-off operation mode, and
discharging by the second circuit and charging by the third circuit are performed in the second turn-off operation mode.

4. The switching drive device according to claim 1, wherein
when the third circuit is a circuit that performs discharging, the first turn-on operation mode is further re-executed after the second turn-on operation mode is executed, and
when the third circuit is a circuit that performs charging, the first turn-off operation mode is further re-executed after the second turn-off operation mode is executed.

5. The switching drive device according to claim 1, further comprising
a detection unit that detects at least one of a voltage, a current, and a temperature of the semiconductor device,
wherein the control device controls on/off of the third switching element based on detection information of the detection unit.

6. The switching drive device according to claim 2, wherein a discharge period of the third circuit in the first turn-off operation mode is set longer as an input voltage of the semiconductor device or a current flowing through the semiconductor device decreases.

7. The switching drive device according to claim 2, wherein a discharge period of the third circuit in the second turn-on operation mode is set longer as an input voltage of the semiconductor £ device, a current flowing through the semiconductor device, or a device temperature of the semiconductor device increases.
